(19) United States
(12) Patent Application Publication
(10) Pub. No.: US 2017/0160629 A1
(43) Pub. Date: Jun. 8, 2017

(54) MODULE FOR COUPLING A LASER DIODE ARRAY

(71) Applicant: BBRIGHT, RENNES (FR)

(72) Inventors: XAVIER HACHAIR, RENNES (FR); AURÉLIA POIVRE, RENNES (FR); GUILLAUME ARTHUIS, RENNES (FR)

(21) Appl. No.: 15/328,013

(22) PCT Filed: Jul. 23, 2015
(86) PCT No.: PCT/FR2015/052038

§ 371 Date: Jan. 20, 2017

(30) Foreign Application Priority Data
Jul. 25, 2014 (FR) 14 57218

(51) Int. Cl. G03B 21/20; G03B 21/16; H01S 5/022; G02B 6/42; H01S 5/024; G02B 19/00; G02B 6/43

(52) U.S. Cl. CPC G03B 21/208; G02B 19/0028; G02B 19/0057; G03B 21/16; G03B 21/2033; G03B 21/2013; G03B 21/2066; G02B 6/43; G02B 6/4214; H01S 5/02423; H01S 5/02236; H01S 5/02284

(57) ABSTRACT

A module to couple a laser diode array, includes a base to support the laser diodes. A network of laser diodes emit laser beams, not necessarily at the same wavelength, towards the outside of the base. The module includes a Cassegrain optical system to focus laser beams emitted by the network of laser diodes. The Cassegrain optical system is made of a convex hyperbolic curved mirror and a concave parabolic curved mirror. The module further includes collimators to concentrate laser beams in a predetermined direction, a coolant to maintain the network of laser diodes at a constant temperature and a PCB card to supply electricity to the network of laser diodes. Preferably, the module is suitable for use in video projection devices.

The field of the present invention is that of optics. The invention is directed to a module for coupling a laser diode array. The present invention finds one particularly advantageous, although in no way limiting, application in videoprojection devices.

### PRIOR ART

Various video projection technologies exist and are used at present. Both for use on screens of very large size, including cinematographic projection, or for personal use in the home on screens of ever increasing size (Home Cinema use).

Although there are multiple technologies, for its part the basic principle always remains the same. Namely to project a light source onto a screen and to subject said light source to various forms of optical processing. The factor common to the most widely used devices is the use of a metal halogen lamp as the light source.

Said devices are then distinguished from one another by the optical technology that they use, the most widespread until now being that of LCD (liquid crystal display) pixels. The LCD pixels, receiving light from said lamp, contain liquid crystals the opacity of which can be varied by the application of an electric current.

The technology using light from a lamp of said kind then evolved and is still undergoing numerous evolutions, for example with LED, DLP (registered trade mark of Texas Instruments), SXRD (registered trade mark of Sony) and D-ILA (registered trade mark of JVC) systems. The most recent evolution concerns the use of red, green and blue laser light sources. There is the possibility of combining this laser technology with the LED technology and with the use of phosphors.

Said technologies are aimed at producing the best possible image quality in terms of various parameters, the most pertinent being contrast, brightness, definition (image sharpness, depending in part on any convergence defects leading to optical and chromatic aberrations) as well as the extent of the color space, referred to as the gamut.

Moreover, the quality of the video projection device is based on criteria such as its noise level in use, its overall size, or the service life of the light source, all this being balanced with the cost of manufacture.

Although, of all the technologies cited, the laser technology is at the cutting edge, from the point of view of image quality, service life of the light source and noise level of the device, its implementation nevertheless continues to slow down its general adoption by customers, given its manufacturing cost and its overall size. Also the difficulty of the task of optimizing the concentration of the light emitted in the smallest possible area, optimality being understood in the sense of minimum light losses and optical and chromatic aberrations. At present this is possible only subject to costly investment, in part because of the optical elements that are necessary (lenses, concentrators, etc.). Also the use of optical elements of long focal length, those lengths having a direct impact on the size of the device used and potentially generating edge effects, or optical fiber combiners, which are particularly costly, making it impossible to automate the method of manufacturing a device of this kind.

### SUMMARY OF THE INVENTION

An objective of the present invention is to remedy some or all of the drawbacks of the prior art, notably those described above, by proposing a solution providing a laser diode array coupling module of compact shape, including an optical system made up of conventional mirrors, and optimally concentrating the light emitted by said laser diode in an area sufficiently small for the resulting light to be used in an optical fiber, for example.

To this end, the invention concerns a laser diode array coupling module, including a base for supporting the laser diodes, an array of laser diodes adapted to emit laser beams, not necessarily at the same wavelength, toward the exterior of the base. The module further includes a Cassegrain optical system adapted to focus laser beams emitted by said laser diode array.

Thanks to the Cassegrain optical system, the laser beams emitted by said laser diodes are focused in an area corresponding to the second focus of said convex mirror and of very small or even point size (of the order of a hundred micrometers). The coupled light obtained at the output of the module can therefore be routed with minimum losses in an optical fiber or some other optical system.

Using curved mirrors moreover makes it possible to reduce the cost of manufacturing the coupling module in that the convex and concave curved mirrors used are conventional and therefore a fortiori designable at lower cost.

Use of a Cassegrain optical system is moreover advantageous because it makes it possible to produce a coupling module of compact shape thanks to a small distance between the laser diodes and the focusing point of said Cassegrain system. Said distance is of the order of a few centimeters whereas other optics (lenses, concentrators, etc.) have a focal length of several tens of centimeters.

In particular embodiments, the laser diode array coupling module may have one or more of the following features, separately or in any technically possible combination.

In one particular embodiment, the laser diode array coupling module includes a convex hyperbolic curved mirror and a concave parabolic curved mirror, said two mirrors forming the Cassegrain optical system.

Using a Cassegrain optical system made up of mirrors of said kind is advantageous where the optimization of the optical convergence of the laser beams is concerned, because:
it is adapted to use a plurality of wavelengths without the focusing point corresponding to the second focus of the convex mirror changing,
it is perfectly stigmatic, and therefore adapted to prevent chromatic aberrations,
it renders optical aberrations (coma, sphericity, etc.) negligible.

In one particular embodiment, the base includes a set of holes adapted to receive collimators, each of said collimators being adapted to concentrate laser beams in a preferential direction.

Using collimator type optics is moreover advantageous because it makes it possible to minimize the divergence of said laser beams.

In one particular embodiment, the base includes a set of holes adapted to cause a cooling liquid to circulate, said cooling liquid being adapted to maintain the laser diode array at a constant temperature.

In one more particular embodiment, the cooling liquid flows through a flow network, the combination of said cooling liquid and said flow network forming a cooling system that may include a plurality of cooling subsystems.

In one more particular embodiment, the base includes a PCB adapted to supply the laser diode array with electrical power.

In one more particular embodiment, the module includes a laser beam collection system positioned at the focusing point of the Cassegrain optical system.

In one more particular embodiment, the collection system includes an IEC connector adapted to receive an optical fiber.

In another more particular embodiment, the collection system includes an optical system for coupling it to an optical fiber or another optical system.

### DESCRIPTION OF THE FIGURES

The features and advantages of the invention will be better appreciated thanks to the following description that describes the features of the invention via a nonlimiting example of its application.

The description refers to the appended figures, which show:

FIG. 1: a diagrammatic perspective view of one embodiment of a laser diode array coupling module device (10).

FIG. 2: a diagrammatic sectional view of one embodiment of a laser diode array coupling module device (10).

FIG. 3: a diagrammatic bottom view of one embodiment of the cooling system inside the base (11) from FIG. 2.

FIG. 4: an image produced by digital simulation of the output of a non-optimized embodiment of a laser diode array coupling module device (10).

FIG. 5: an image produced by digital simulation of the output of an optimized embodiment of a laser diode array coupling module device (10).

In these figures, references identical from one figure to another designate identical or analogous elements. For clarity, those elements are not represented to scale unless otherwise indicated.

### DETAILED DESCRIPTION OF EMBODIMENTS OF THE INVENTION

The field of the present invention is that of videoprojection.

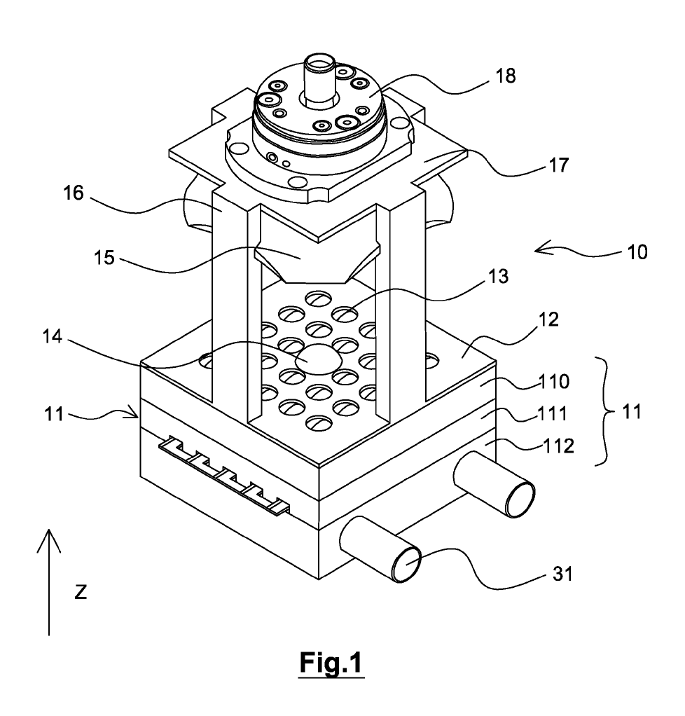

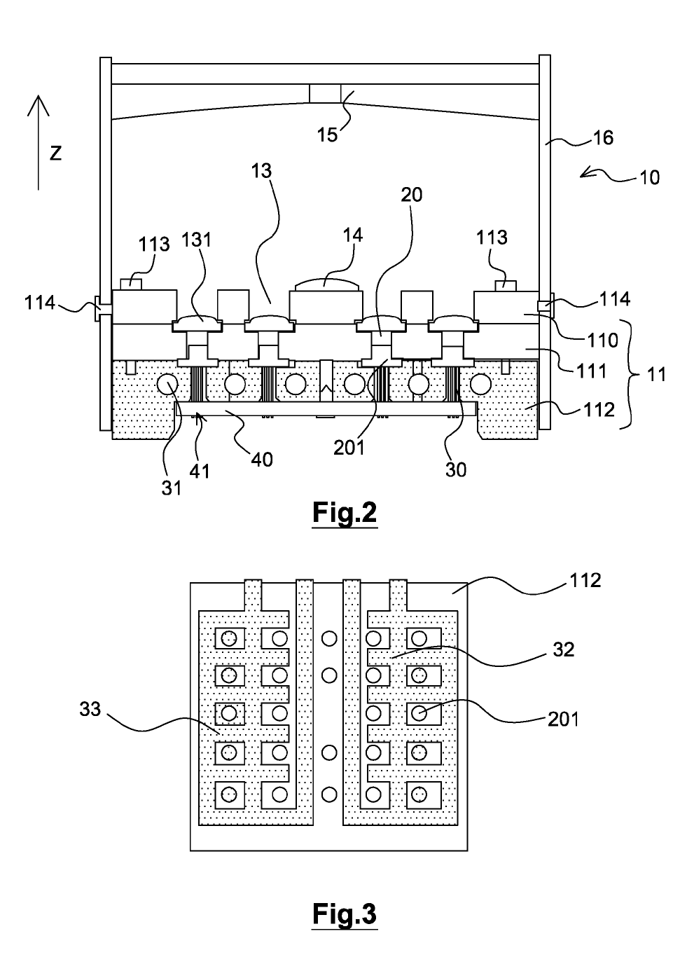

FIG. 1 and FIG. 2 are diagrammatic representations of one embodiment of a laser diode array coupling module (10) and respectively correspond to a perspective view of the outside of said module (10) and a sectional view of said module (10). By way of nonlimiting example, said module (10) is used by a video projection system (not shown). Said video projection system is for example a cinematographic projector using lasers as the only light sources.

The laser diode array coupling module (10) includes a base (11) to support the laser diodes.

For the remainder of the description an axis Z is defined relative to this laser diode array coupling module (10). The direction of said axis Z is normal to the plane on which the base (11) rests and said axis is oriented in said plane toward the base (11), it being understood that the upward direction of movement corresponds to the direction of orientation of the axis Z. Said axis Z is shown by way of nonlimiting example in FIGS. 1 and 2.

The concepts of top, bottom, upper, lower, under, above, etc. in relation to the diode array coupling module (10) are defined relative to this axis Z.

The remainder of the description adopts the convention that a normal to the face of any object is always oriented from the interior toward the exterior of said object.

The base (11) includes three plates (110), (111) and (112), not necessarily with equal volumes, fastened to one another and to the base (11) and superposed on one another so that said plate (111) is between the plates (110) and (112) and said plate (112) rests on the plane on which said base (11) rests. Said plates (110), (111) and (112) and the base (11) have a plurality of faces, in particular so-called lateral faces corresponding to the faces having a normal orthogonal to the axis Z. Each of said plates (110), (111) and (112) has a number of lateral faces greater than or equal to the number of lateral faces of said base (11). Moreover, said plates (110), (111) and (112) are superposed so that their lateral faces having a normal in the same direction on the same axis are coplanar and each of said coplanar faces is in contact with a lateral face of said base (11).

Moreover, the base (11) and the plates (110), (111) and (112) are rigid and machined from metal. Said machining is preferably effected on a piece of aluminum.

In one particular embodiment, the machining of the base (11) and the plates (110), (111) and (112) is preferably effected on a piece of copper. The use of a method of this kind is advantageous because of the increase in the thermal transfer capacity of the various parts of the module (10) but is not considered to be the preferred option because of its cost.

In other particular embodiments, the machining of the base (11) and the plates (110), (111) and (112) is effected on a piece of metal having a thermal conductivity and a stiffness adapted to ensure the integrity of the module (10) when in operation.

In the nonlimiting example illustrated by FIGS. 1 and 2, the base (11) and the plates (110) and (111) are of rectangular parallelepiped shape. The plate (112) is produced from an initial rectangular parallelepiped plate from which a secondary rectangular parallelepiped plate has been removed and contained in said initial plate so that the lower face of said secondary plate is contained in the lower face of said initial plate. Moreover, the lower face of said secondary plate is centered relative to the lower face of said initial plate. In other examples that are not described there is nothing to rule out other geometries.

In the nonlimiting example illustrated by FIG. 2, the plates (110), (111) and (112) are fastened together by screws (113). Each of said screws (113) passes through the plates (110), (111) and (112) parallel to the axis Z and is screwed downward so that its head rests on the plate (110). Moreover, the plate (110) is fastened to the base (11) by screws (114). Each of said screws (114) passes through the plate (110) orthogonally to the axis Z and is screwed toward the interior of the base (11) so that its head rests on the base (11).

The base (11) and the plate (110) have a common upper face (12), necessarily plane and orthogonal to the axis Z, and feature a set of holes (13), said set being centered relative to said upper face (12). Said holes (13) pass completely through the plate (110), each including a lower hole and an upper hole that are not physically separated and respectively bear on the lower and upper faces of the plate (110). Said upper hole of a hole (13) is of cylindrical shape with its axis of revolution parallel to the axis Z. In particular, said upper hole of a hole (13) has for its base an upper disk contained in the upper face (12) and a lower disk centered relative to the lower hole of said hole (13) and strictly contained in said lower hole. In the remainder of the description, the upper disk of an upper hole of a hole (13) is referred to as the upper disk of said hole (13).

In the nonlimiting example illustrated by FIG. 1, the upper face (12) is square and features a set of identical holes (13). Said holes (13) are distributed uniformly in a square matrix array missing its central element. Said square matrix array is disposed so that a virtual polygonal line passing through the centers of the upper disks of the upper holes constituting said holes (13) situated at the edge form a square the axes of symmetry of which coincide with those of the square formed by the upper face (12). In other examples that are not described there is nothing to rule out having holes (13) organized according to a matrix array of a geometrical shape other than square.

More particularly, in the embodiment illustrated by FIG. 1, said matrix array is based on a square made up of twenty-five holes. Said square is constructed so that each of its sides includes five regularly spaced holes (13), each end of one of said sides being the center of one of the upper disks of said five holes. The other holes (13), constituting the interior of the matrix array, are disposed so that the centers of their respective upper disks conform to the condition of uniform distribution. Finally, the matrix array is produced by depriving the square of twenty-five holes of its central element, that is to say the hole (13) the upper disk of which is centered on the point of intersection of the diagonals of said square.

In one particular embodiment, the square matrix array formed by the holes (13) is of size n²-p²:
n being a natural integer strictly greater than 2,
p being a strictly positive natural integer strictly less than n,
n and p having the same parity.

Said matrix array is then based on a first square made up of n² regularly spaced holes from which are removed p² regularly spaced holes forming a second square, the axes of symmetry of said second square coinciding with those of said first square.

Moreover, the holes (13) are adapted to receive collimation optics, termed collimators (131), each of said collimators (131) being adapted to concentrate laser beams in a preferential direction. Said collimators (131) rest on a base adapted to be nested in the lower holes of said holes (13).

In the nonlimiting example illustrated by FIGS. 1 and 2, the collimators (131) placed in the holes (13) are adapted to deflect laser beams coming from the bottom of the plate (110) so that the resulting laser beams are parallel to the axis Z and directed toward the top of the base (11).

In one particular embodiment, the holes (13) are not all identical, differing in the size of their respective lower and upper holes, and so the collimators (131) placed in said holes (13) are not all identical.

The plate (111) includes a set of holes (20), each of said holes (20) being situated facing a single hole (13). Said holes (20) pass completely through the plate (111), each including a lower hole, an upper hole, and an intermediate hole, that are not physically separated and are arranged so that said intermediate hole is between said lower and upper holes. Moreover, said lower and upper holes rest on the lower and upper faces, respectively, of the plate (111). Said intermediate hole of a hole (20) is cylindrical with its axis of revolution parallel to the axis Z and coinciding with the axis of revolution of the upper hole of the facing hole (13). In particular, said intermediate hole of a hole (20) has for its base lower and upper disks centered relative to said lower and upper holes, respectively, of said hole (20), and strictly contained within the latter.

As shown in FIG. 2, the upper holes of the holes (20) are arranged so that the base of the collimators (131) is nested therein. In this way, the upper holes of the holes (20) and the lower holes of the holes (13) are adapted to retain the collimators (131) by compression in a fixed position between the plates (110) and (111) and along the axis Z.

In one particular embodiment, in addition to being held fixed by compression between the plates (110) and (111), the collimators (131) are stuck to said plates (110) and (111).

Moreover, the holes (20) are adapted to receive an array of laser diodes (201), said diodes being disposed so as to emit laser beams, that are not necessarily at the same wavelength, in a preferential direction, toward the outside of the base (11), i.e. toward the top of the module (10). Said diodes (201) rest on a base adapted to be nested in the lower holes of said holes (20).

In the nonlimiting example illustrated by FIG. 2, the diodes (201) placed in the holes (20) are adapted to deflect laser beams coming from the bottom of the plate (111) so that the resulting laser beams are parallel to the axis Z and directed toward the top of the base (11).

In one particular embodiment, the laser diodes are of TO56 type. These diodes are characterized by a base, on which they rest, of 5.6 mm diameter and an emission spectrum that can range from ultraviolet to infrared.

In another particular embodiment, the laser diodes are of TO9 type. These diodes are characterized by a base, on which they rest, of 9 mm diameter and an emission spectrum that can range from ultraviolet to infrared.

In one particular embodiment, the holes (20) are not all identical, differing in terms of the size of their respective lower, intermediate and upper holes, and so the diodes (201) placed in said holes (13) are not all identical.

The plate (112) includes a set of holes (30), each of said holes (30) being situated facing a single hole (20). Said holes (30) pass completely through the plate (112), each including a lower hole and an upper hole, not physically separated, and respectively bearing on the lower and upper faces of the plate (112). Said lower hole of a hole (30) is cylindrical with its axis of revolution parallel to the axis Z and coinciding with the axis of revolution of the intermediate hole of the facing hole (20). In particular, said lower hole of a hole (30) has for its base an upper disk centered relative to the upper hole of said hole (30) and strictly contained within said upper hole.

As shown in FIG. 2, the upper holes of the holes (30) are arranged so that the base of the diodes (201) is nested therein. In this way, the upper holes of the holes (30) and the lower holes of the holes (20) are adapted to retain the diodes (201) by compression in fixed position between the plates (111) and (112) and in the direction of the axis Z. Moreover, the lower hole of each hole (30) is then advantageously configured so that the anode and the cathode of each diode, retained by compression between the plates (111) and (112), is accommodated therein.

In one particular embodiment, as well as being fixed by compression between the plates (111) and (112), the diodes (201) are stuck to said plates (111) and (112).

The plate (112) also includes on at least one of its lateral faces a set of holes (31) adapted to cause a cooling liquid to circulate in said plate (112) from the outside of the base (11). Said cooling liquid is adapted to maintain the array of laser diodes placed in the holes (30) at a constant temperature. Said cooling liquid flows through a cooling network (not shown in FIG. 2), the combination of said cooling liquid and said cooling network forming a cooling system.

Moreover, the number of holes (31) is greater than or equal to two, so that at least one of said two holes (31) constitutes the inlet of the cooling system, leading from the outside toward the inside of the base (11), and at least one of said two holes (31) constitutes the outlet of the cooling system, leading from the inside toward the outside of the base (11).

In the nonlimiting example illustrated by FIG. 2, the six holes (31) are of cylindrical shape, have an axis of revolution orthogonal to the lateral face through which they are formed and have disks for their base. In particular, the external disk of a hole (31) is that contained within the external lateral face (22). Said cylindrical holes (31) are regularly spaced and disposed so that the centers of the disks serving as their base are aligned along a straight line segment parallel to the side of the square upper face (12) on which said lateral face rests. In other examples that are not described there is nothing to rule out holes (31) with a geometrical shape other than cylindrical.

In one particular embodiment, the cooling liquid of the cooling system is water. In other examples that are not described there is nothing to rule out using other liquids.

FIG. 3 is a diagrammatic representation of a bottom view of one embodiment of the system referred to above for cooling the base (11).

In the nonlimiting example illustrated by FIG. 3, the flow network of the cooling system consists of pipes. Said pipes form two cooling subsystems (32) and (33) that do not communicate with each other and are adapted to cause the cooling liquid to flow around the holes (30) in the plate (112). Each cooling subsystem (32) or (33) includes an inlet/outlet system formed by two cylindrical holes (31), one being adapted to cause the cooling liquid to enter the interior of the base (11) and the other being adapted to cause the cooling liquid to exit the base (11) to the outside. In other embodiments that are not described there is nothing to rule out having other geometries of the flow networks of the cooling system and a number of cooling subsystems other than two.

The base (11) also includes a printed circuit board (PCB) (40) adapted to supply the array of laser diodes (201) placed in the holes (20) with electrical power. Said PCB (40) is moreover adapted to be nested in the underside of the base (11) so that it is in contact with the plate (112).

In one particular embodiment, the PCB (40) is a rigid printed circuit board.

In one particular embodiment, the PCB (40) is a flexible printed circuit.

Moreover, said PCB (40) includes means for retaining in a fixed position anodes and cathodes of the diodes (201) placed in the holes (20). A configuration of this kind, coupled to that making it possible to retain the diodes (201) by compression in a fixed position between the plates (111) and (112) is advantageous for ensuring optimum retention of said diodes (201).

In one particular embodiment, and as shown in FIG. 2, the means for retaining in a fixed position the anodes and cathodes of the diodes (201) placed in the holes (20) consist of a set of holes (41) passing completely through the PCB (40) and adapted to receive said anodes and said cathodes. The anodes and the cathodes passing through said holes (41) in the PCB (40) are preferably soldered to the PCB (40), the soldering being effected at the level of the lower face of said PCB (40). A configuration of this kind is advantageous for retaining the PCB (40) in contact with the plate (112). In other embodiments that are not described there is nothing to rule out using other means for holding the PCB (40) in contact with the plate (112).

The laser diode array coupling module (10) includes a convex hyperbolic curved mirror (14). Said convex mirror (14) has an optical axis parallel to the axis Z and a surface consisting of a hyperboloid with the apex facing toward the top of the module (10). Said hyperboloid rests on a disk, said disk forming the base of said convex mirror (14), and is centered on the upper face (12) of the plate (110). Said convex mirror (14) further has a first focus situated under the base of the mirror and a second focus situated above said hyperboloid.

The laser diode array coupling module (10) includes a concave parabolic curved mirror (15). Said concave mirror (15) has a hole at its optical center, an optical axis parallel to the axis Z, and a surface consisting of a paraboloid with the apex facing toward the bottom of the module (10). Said concave mirror (15) also has a single focus situated under said paraboloid.

The concave mirror (15) and the convex mirror (14) form a so-called “Cassegrain” optical system. To this end, the relative position of concave mirror (15) and the convex mirror (14) is adapted to cause their respective optical axes to coincide and the single focus of the concave mirror (15) to coincide with the first focus of the convex mirror (14) so that the second focus of the optical mirror (14) is situated under the concave mirror (15). Said Cassegrain optical system is adapted to focus laser beams emitted by the laser diodes parallel to the axis Z above the base (11) at a focusing point corresponding to the second focus of the convex mirror (14).

In the nonlimiting example illustrated by FIGS. 1 and 2, the disk of the base of the convex mirror (14) is centered on the point of intersection of the diagonals of the square formed by the upper face (12). Moreover, said convex mirror (14) is nested in and stuck to said upper face (12). The concave mirror (15) is held above the convex mirror (14) so as to form a Cassegrain system as described above by four identical, rigid, parallelepipedal rods (16) produced by machining aluminum. Said rods (16) have a longitudinal axis parallel to the axis Z, each being supported by a separate side of the upper face (12). Moreover, the section of a rod (16) in a plane containing the upper face (12) is a rectangle strictly contained within the upper face (12) and centered along the side of the upper face (12) supporting said rod (16). In other examples that are not described there is nothing to rule out using rods (16) produced by machining a piece of metal other than aluminum. More generally, in other examples that are not described there is nothing to rule out using other mechanical systems to hold the concave mirror (15) at a distance from the convex mirror (14) so that said concave mirror (15) and said convex mirror (14) form a Cassegrain system.

The use of a Cassegrain optical system is advantageous where the optimization of the optical convergence of the laser beams coming from the laser diodes (201) is concerned. While the relative position of the concave mirror (15) and the convex mirror (14) is a decisive criterion in the capacity of the Cassegrain system to couple said laser beams, with limited light losses, the geometrical parameters of said mirrors are just as fundamental.

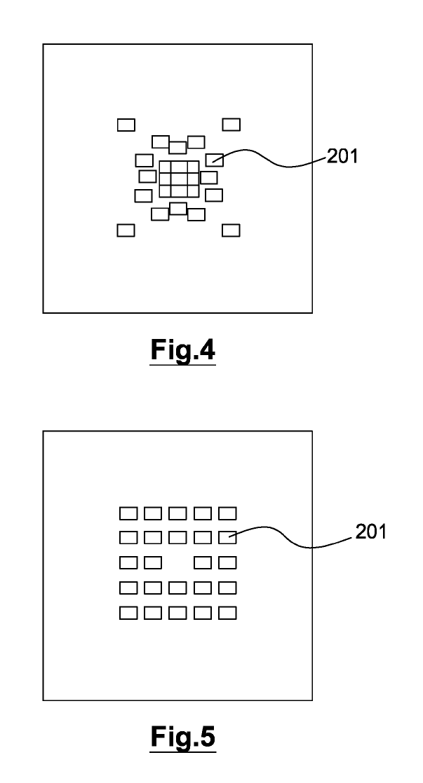

FIG. 4 and FIG. 5 represent images produced by digital simulation the output of respectively optimized and non-optimized embodiments of a laser diode array coupling module device (10).

In the nonlimiting example illustrated by FIG. 4, the concave mirror (15) and the convex mirror (14) are configured so that their conic constant is zero; in other words said mirrors are spherical but still form a Cassegrain system. Observation of the image produced at the outlet of the module (10), i.e. just behind the concave mirror (15) and on its optical axis, conventionally shows the astigmatism of the optical system and the presence of edge effects. Modification of the conical constants of the mirrors then makes it advantageous to employ a Cassegrain optical system.

More particularly, in the nonlimiting example illustrated by FIG. 5, the conic constants of the concave mirror (15) and the convex mirror (14) used for the FIG. 4 digital simulation were modified so that said concave mirror (15) is a paraboloid with conic constant equal to −1 and said mirror (14) is a hyperboloid with conic constant equal to −2.37. Observation of the image produced at the outlet of the module (10), i.e. just behind the concave mirror (15) and on its optical axis, shows a clear reduction of the astigmatism and edge effects compared to FIG. 4.

In one particular embodiment, the laser diode array coupling module device (10) includes a laser beam collection system positioned at the focusing point of the Cassegrain system and adapted to collect the beams from the laser diodes (201) focused by the Cassegrain optical system.

In a more particular embodiment, said collection system includes an IEC (International Electrotechnical Commission) optical fiber connector.

In an even more particular embodiment, shown by way of nonlimiting example in FIG. 1, the collection system includes an SMA connector (18) adapted to receive an optical fiber. Said SMA connector is embedded in a square plate (17) orthogonal to the axis Z and situated above the concave mirror (15). Each of the sides of said square plate (17) is moreover supported by contact with a rod (16) so as to retain said plate (17) in a fixed position. More particularly, said contact occurs between said plate (17) and the faces of the rods (16) of greatest area and with a normal oriented toward the interior of the upper face (12). In other embodiments that are not described there is nothing to rule out the SMA connector being held in position by some other mechanical system.

In another more particular embodiment, said collection system includes an optical system, said optical system including a nonlimiting number of parts, said parts being adapted to apply to the laser beams any one or any combination of the following actions: reflection, refraction, diffusion, diffraction, filtering.

In an even more particular embodiment, said optical system is adapted to be coupled to an optical fiber or another optical system.

More generally, it is to be noted that the embodiments considered above have been described by way of nonlimiting example and that other variants can therefore be envisaged.

In particular, the invention has been described in relation to the field of videoprojection. In other examples there is nothing to rule out its use for laser cutting, laser pumping, laser epilation or illumination.

1-9. (canceled)

10. A module to couple a laser diode array, comprising: a base to support a network of laser diodes of the laser diode array, the network of laser diodes emitting laser beams, not necessarily at a same wavelength, toward the outside of the base; and a Cassegrain optical system to focus the laser beams emitted by the network of laser diodes, the Cassegrain optical system comprising a concave parabolic curved mirror.

11. The module according to claim 10, wherein the Cassegrain optical system further comprises a convex hyperbolic curved mirror, the convex hyperbolic curved mirror and the concave parabolic curved mirror are arranged so that their respective optical axes coincide.

12. The module according to claim 10, wherein the base comprises a set of holes configured to receive collimators, each collimator concentrates laser beams in a predetermined direction.

13. The module according to claim 10, wherein the base comprises a set of holes configured to cause a cooling liquid to circulate, the cooling liquid maintains the network of laser diodes at a constant temperature.

14. The module according to claim 13, wherein the cooling liquid flows through a flow network, the combination of the cooling liquid and the flow network forms a cooling system.

15. The module according to claim 14, wherein the cooling system comprises a plurality of cooling subsystems.

16. The module according to claim 10, wherein the base further comprises a PCB to supply the laser diode array with an electrical power.

17. The module according to claim 10, further comprising a laser beam collector positioned at a focusing point of the Cassegrain optical system.

18. The module according to claim 17, wherein the laser beam collector comprises an IEC connector to receive an optical fiber.

19. The module according to claim 17, wherein the laser beam collector comprises an optical system to couple the optical system to an optical fiber or another optical system.

20. The module according to claim 11, further comprising a laser beam collector positioned at a focusing point of the Cassegrain optical system, the laser beam collector comprises an IEC connector to receive an optical fiber.

21. The module according to claim 11, further comprising a laser beam collector positioned at a focusing point of the Cassegrain optical system, the laser beam collector comprises an optical system to couple the optical system to an optical fiber or another optical system.

22. The module according to claim 12, further comprising a laser beam collector positioned at a focusing point of the Cassegrain optical system, the laser beam collector comprises an IEC connector to receive an optical fiber.

23. The module according to claim 12, wherein it includes a laser beam collection system positioned at the focusing point of the Cassegrain optical system, the collection system including an optical system for coupling the optical system to an optical fiber or another optical system.
